(19) United States
(12) Patent Application Publication
(10) Pub. No.: US 2014/0231127 A1
(43) Pub. Date: Aug. 21, 2014

(54) Multi-Finish Printed Circuit Board

(71) Applicant: LUTRON ELECTRONICS CO., INC., Coopersburg, PA (US)

(72) Inventor: David Manero, Perkasie, PA (US)

(73) Assignee: LUTRON ELECTRONICS CO., INC., Coopersburg, PA (US)

(21) Appl. No.: 13/770,467

(22) Filed: Feb. 19, 2013

(51) Int. Cl. H05K 3/28; H05K 1/11

(52) U.S. Cl. CPC H05K 3/28; H05K 1/115; H05K 1/111
USPC 174/266; 427/96.2

(57) ABSTRACT

A multi-finish printed circuit board may include one or more electrically conductive elements, such as through hole pads, that may have a first surface finish and one or more electrically conductive elements, such as surface mount pads, that may have a second surface finish that is different from the first surface finish. The first surface finish may be a hot air solder leveling (HASL) surface finish or a lead-free hot air solder leveling (LF HASL) surface finish and the second surface finish may be an organic surface protector (OSP) surface finish. The second surface finish may be applied to one or more electrically conductive elements from which the first surface finish was removed.

### BACKGROUND

Typical printed circuit boards (PCBs) include electrically conductive elements, such as plated through holes and surface mount pads, for receiving electronic components that are to be affixed to the PCB. Typically, to affix the electronic components to the PCB, the electronic components are soldered to the electrically conductive elements.

To improve solderability, and to prevent oxidation of the electrically conductive elements prior to one or more soldering processes, a surface finish is typically applied to the PCB before the electronic components are affixed to the PCB. Examples of such surface finishes include hot air solder leveling (HASL), lead-free hot air solder leveling (LF HASL), organic surface protection (OSP), immersion tin, immersion silver, electroless nickel immersion gold (ENIG), and electroless nickel electroless palladium immersion gold (ENEPIG), among others. A typical PCB is finished with only a single such surface finish. Such a PCB may be referred to as a single-finish PCB.

FIG. 1 is a flow diagram of a prior art process 100 for manufacturing a single-finish PCB. FIG. 2 depicts a prior art single-finish PCB 200 manufactured in accordance with the process illustrated in FIG. 1.

The illustrated prior art PCB manufacturing process 100 begins at 102, where a raw material substrate is provided. The substrate may have a substrate body that defines first and second, substantially flat, opposed surfaces. The first and second surfaces may be spaced apart from one another, and may be bounded by a shared outer perimeter. The substrate may include a copper foil bonded to one or both of the first and second surfaces of the substrate body.

At 104, one or more through holes 202 may be drilled through the substrate. The through holes may extend from the first surface of the substrate through to the second surface of the substrate. The through holes 202 may be arranged in any desirable arrangement, and are typically arranged in accordance with a printed circuit layout, or pattern, associated with the printed circuit board 200.

At 106, the inner surfaces of the through holes 202 may be plated with an electrically conductive material, such as copper, for example. The electrically conductive material allows for electrical conductivity via the through holes between the first and second sides of the substrate.

At 108, a protective film, such as a layer of negative photoresist, is applied to one or both of the first and second surfaces of the substrate. At 110, a photomask that is representative of the printed circuit layout associated with the printed circuit board 200 is disposed on the protective film. The photomask may have one or more dark areas that correspond to the printed circuits of the printed circuit board 200. The rest of the photomask may be substantially clear. The protective film is cured with the photomask in place. For example, the substrate may be exposed to ultraviolet light, such that areas of the protective film that are covered by clear areas of the photomask are cured, while areas of the protective film that are covered by dark areas of the photomask remain uncured.

At 112, the photomask may be removed from the substrate and respective uncured areas of the protective film that correspond to the printed circuits of the printed circuit board 200 may be stripped from the substrate. For example, the substrate may be exposed to a developing agent, in order to expose the underlying copper foil of the substrate in the areas formerly covered by the uncured protective film.

At 114, a conductive material, such as copper, may be applied to the areas of the substrate that were formerly covered by the uncured protective film. For example, copper may be electroplated onto the respective areas of exposed copper foil, thereby defining the printed circuits. The printed circuits of the illustrated printed circuit board 200 include electrically conductive through hole pads 204 that correspond to respective through holes 202, electrically conductive surface mount pads 206, and electrically conductive traces 208 that electrically connect respective electrically conductive elements of the printed circuit board 200 to one another.

At 116, the plated copper corresponding to the printed circuits is coated with a protective material, such as a layer of tin, for example. At 118, the areas of cured protective film are stripped from the substrate, and the underlying areas of copper foil formerly covered by the areas of cured protective film are etched from the substrate. The protective material may operate to prevent oxidation of the copper and/or to protect the electrical circuits during the etching process.

At 120, the protective material is etched from the electrical circuits and a solder mask is applied to the surfaces of the substrate that do not correspond to electrical component pads of the printed circuit board 200, defining solder masked portions 210 of the electrical traces 208 and solder masked portions 212 of the printed circuit board 200. Thus, the copper that forms the through hole pads 204 and the surface mount pads 206 remains exposed.

At 122, a single surface finish is applied to the electrical component pads, including the through hole pads 204 and the surface mount pads 206. The surface finish may enhance solderability characteristics of the electrical component pads and may prevent oxidation of the copper of the electrical component pads prior to the mounting and soldering of respective electrical components to the printed circuit board 200.

The electrical component pads of the illustrated prior art printed circuit board 200 may be finished with a single hot air solder leveling (HASL) surface finish 214 or a single lead-free hot air solder leveling (LF HASL) surface finish. Other materials that may be applied as a single surface finish include organic surface protection (OSP), immersion tin, immersion silver, electroless nickel immersion gold (ENIG), electroless nickel electroless palladium immersion gold (ENEPIG), or any other suitable surface finish material.

The various surface finishes have different characteristics that may make them more or less desirable for a particular application. For example, HASL surface finish is typically desirable for through hole pads, as HASL surface finish tends to enhance solderability. Enhancing the solderability of the through hole pads may improve the quality and/or reliability of respective electrical connections between the through hole mount electrical components and the printed circuit board. Because HASL surface finish is itself a solder material, finishing the through hole pads of a printed circuit board with HASL surface finish may enhance corresponding soldering processes that electrically connect through hole mount electrical components to the printed circuit board, such that IPC Class 2 standards or better may be achieved. However applying HASL surface finish as a single surface finish on the electrical component pads of a printed circuit board typically results in a rough, uneven surface on one or more small surface mount pads (e.g., small surface mount pads) of the printed circuit board, which may degrade the quality and/or reliability of respective electrical connections between surface mount electrical components and the printed circuit board, for example as established during one or more reflow soldering processes.

By contrast, OSP surface finish is typically desirable for surface mount pads. A single surface finish of OSP surface finish may result in a uniform, substantially flat, solderable surface across the surface mount pads of the printed circuit board, which may enhance the likelihood that each surface mount pad receives an appropriate amount of solder paste during a solder paste application process, such as a solder paste screen printing process. Uniform application of solder paste across the surface mount pads may enhance one or more corresponding reflow soldering process that electrically connect surface mount electrical components placed on the surface mount pads, such that IPC Class 2 standards or better may be achieved. However OSP surface finish typically begins to break down in the presence of heat. For example, an OSP surface finish on the through hole pads of a printed circuit board may break down if the printed circuit board is exposed to one or more reflow processes before through hole mount electrical components are soldered to the printed circuit board, which may degrade the quality and/or reliability of respective electrical connections established between the through hole mount electrical components and the printed circuit board.

Accordingly, a printed circuit board with electrical component pads having a single HASL or LF HASL surface finish typically has through hole pads that exhibit desirable solderability characteristics and surface mount pads that exhibit undesirable solderability characteristics. Moreover, a printed circuit board with electrical component pads having a single OSP surface finish typically has surface mount pads that exhibit desirable solderability characteristics and through hole pads that exhibit undesirable solderability characteristics.

A printed circuit board with electrical component pads having a single ENIG surface finish typically has through hole pads and surface mount pads that exhibit acceptable levels of solderability, respectively. However ENIG surface finish is significantly more expensive than HASL or OSP surface finishes. Consequently, employing a single ENIG surface finish on the electrical component pads of a printed circuit board is typically cost prohibitive.

It would be desirable, therefore, to provide a process for manufacturing a multi-finish PCB. Such a process would be particularly desirable if the process provided for through hole pads having a first surface finish, such as HASL surface finish, for example, and surface mount pads having a second surface finish, such as OSP surface finish, for example.

### SUMMARY

A printed circuit board may include a substrate body. A first electrically conductive element, such as a through hole pad, may be disposed on the substrate body. The first electrically conductive element may have a first surface finish, such as a HASL surface finish or an LF HASL surface finish, for example. A second electrically conductive element, such as a surface mount pad, may also be disposed on the substrate body. The second electrically conductive element may have a second surface finish that is different from the first surface finish. The second surface finish may be OSP surface finish, for example.

A method for manufacturing a printed circuit board may include providing a substrate having a substrate body and first and second electrically conductive elements disposed on the substrate body. A first surface finish may be applied to the first electrically conductive element. A second surface finish may be applied to the second electrically conductive element, wherein the second surface finish is different from the first surface finish.

### BRIEF DESCRIPTION OF THE DRAWINGS

FIG. 1 is a flow diagram of a prior art process for manufacturing a single-finish printed circuit board.

FIG. 2 depicts a prior art printed circuit board manufactured in accordance with the process illustrated in FIG. 1.

FIG. 3 is a flow diagram of a process for manufacturing a multi-finish printed circuit board.

FIG. 4A depicts a raw material substrate that may be used in the process illustrated in FIG. 3.

FIG. 4B depicts the substrate illustrated in FIG. 4A with a plurality of holes drilled there through.

FIG. 4C depicts the substrate illustrated in FIG. 4B after a protective film and a photomask have been applied to the substrate.

FIG. 4D depicts the substrate illustrated in FIG. 4C after the protective film has been cured with the photomask in place, the photomask has been removed, and respective uncured portions of the protective film have been removed.

FIG. 4E depicts the substrate illustrated in FIG. 4D after a conductive material has been plated onto the substrate in areas where the uncured portions of protective film were removed.

FIG. 4F depicts the substrate illustrated in FIG. 4E after cured portions of the protective film and a foil layer of the substrate, respectively, have been removed.

FIG. 4G depicts the substrate illustrated in FIG. 4F after the electrically conductive pads have been covered with a mask, a non-conductive layer has been applied to areas of the substrate not covered by the mask, and the mask has been removed.

FIG. 4H depicts the substrate illustrated in FIG. 4G after a first surface finish has been applied to the electrically conductive pads.

FIG. 4I depicts the substrate illustrated in FIG. 4H after the through hole pads have been covered by a protective film mask.

FIG. 4J depicts the substrate illustrated in FIG. 4I after the first surface finish has been stripped from the electrically conductive surface mount pads that were not covered by the protective film mask.

FIG. 4K depicts the substrate illustrated in FIG. 4J after the protective film mask applied to through hole pads has been removed.

FIG. 4L is a top view of the substrate illustrated in FIG. 4K after a second surface finish has been applied to the surface mount pads that were not covered by the protective film mask.

FIGS. 5A and 5B provide a detailed flow diagram illustrating an example process for manufacturing a multi-finish PCB in accordance with the process illustrated in FIG. 3.

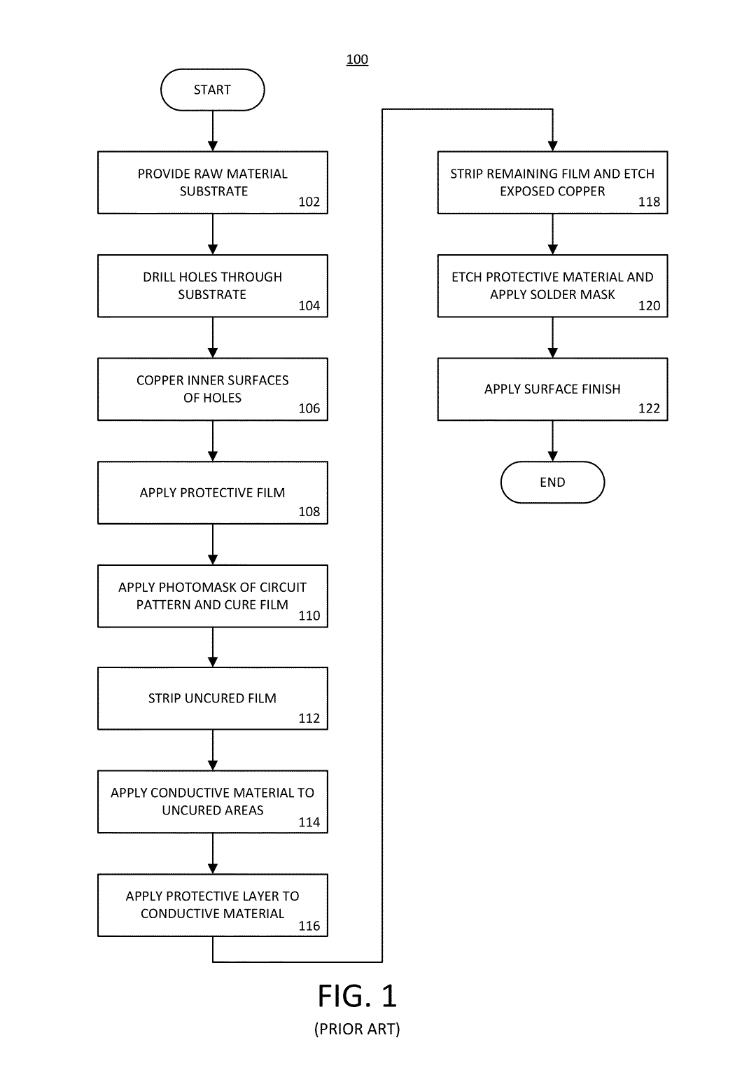

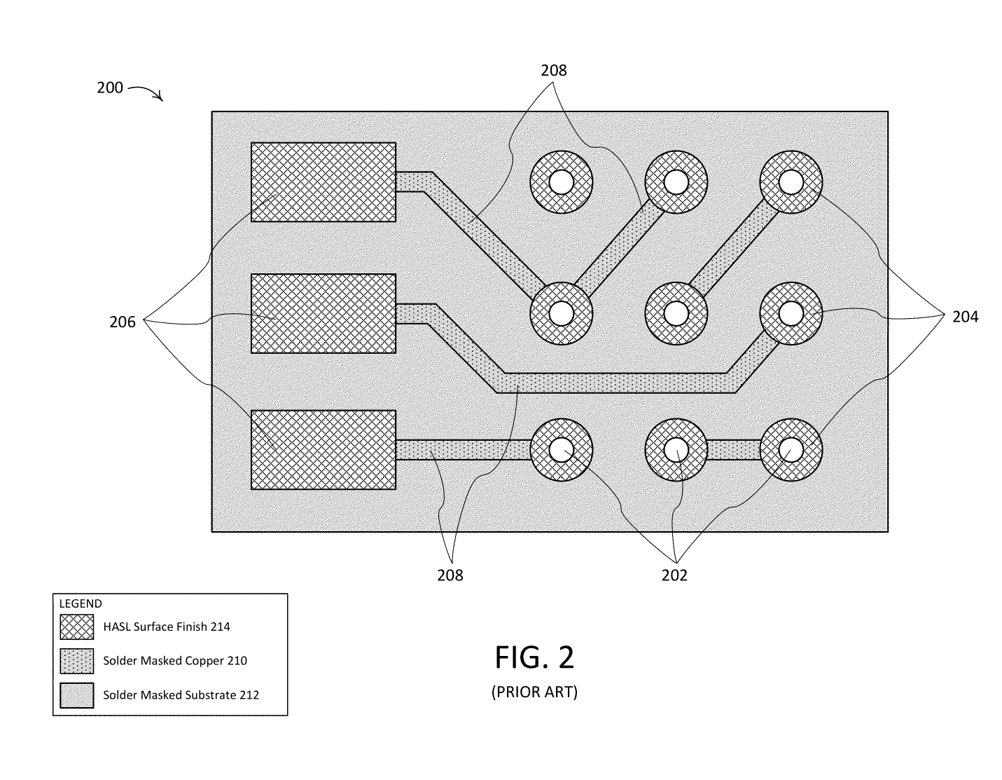

### DETAILED DESCRIPTION

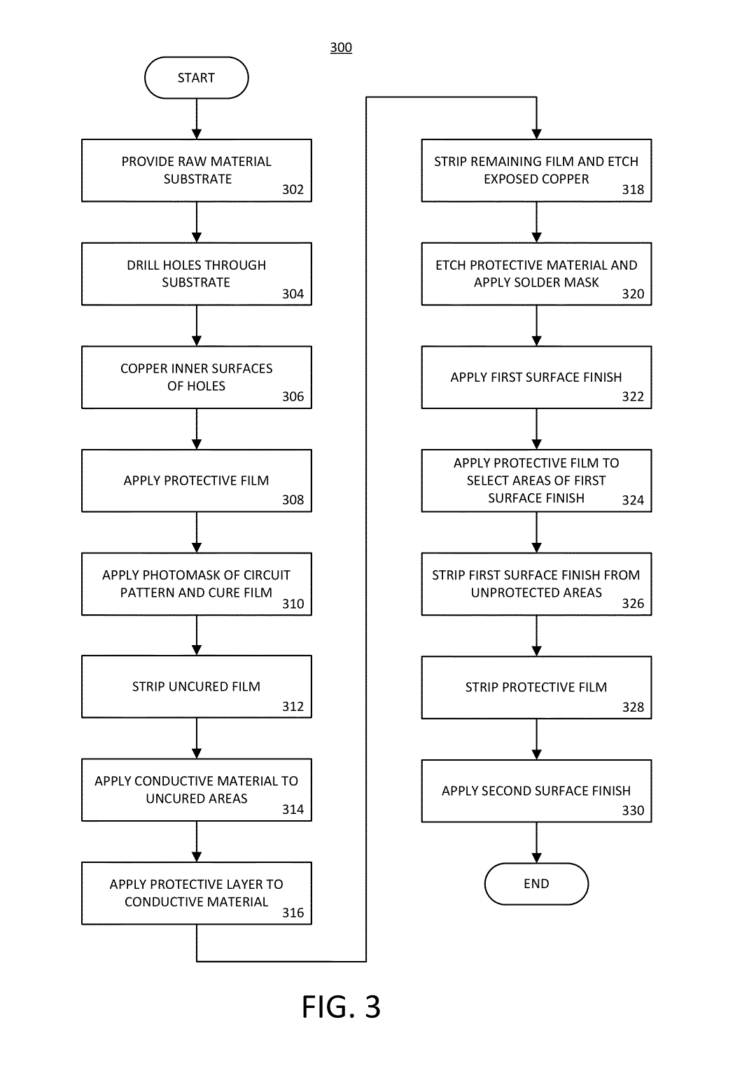

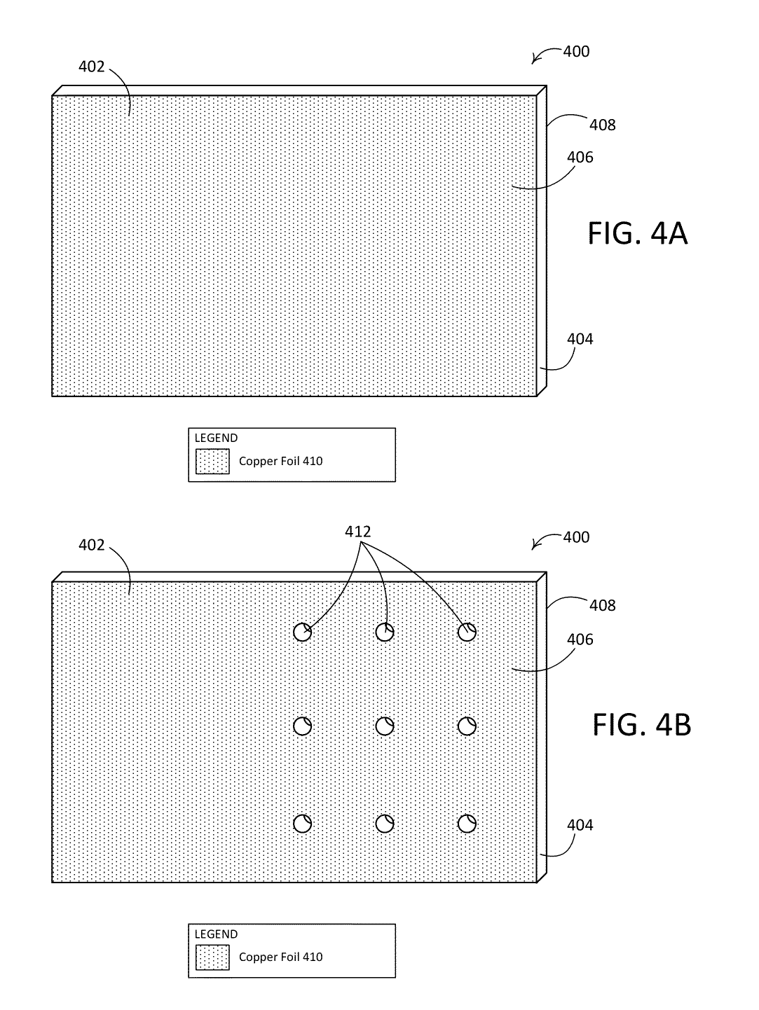

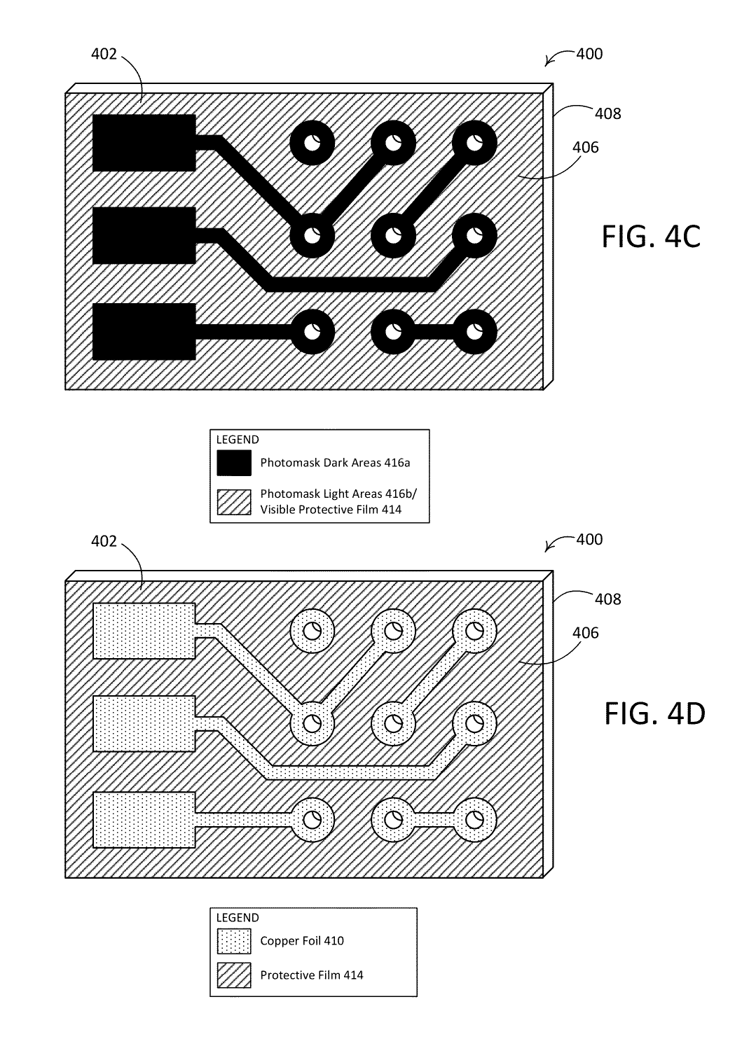

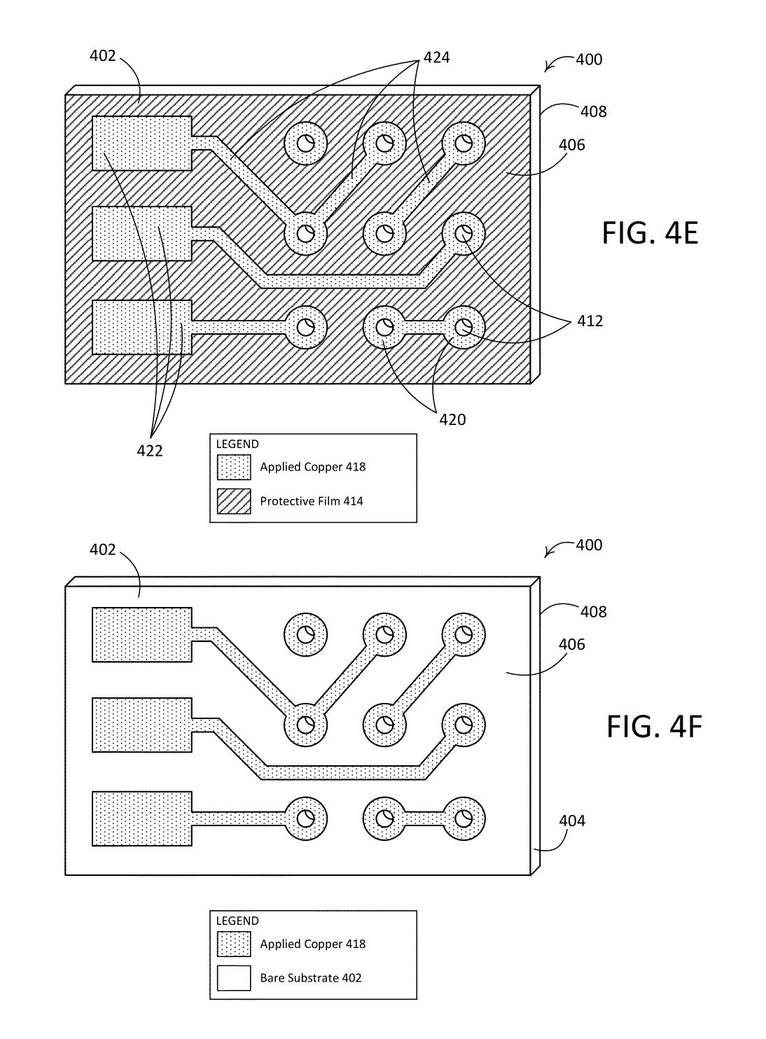

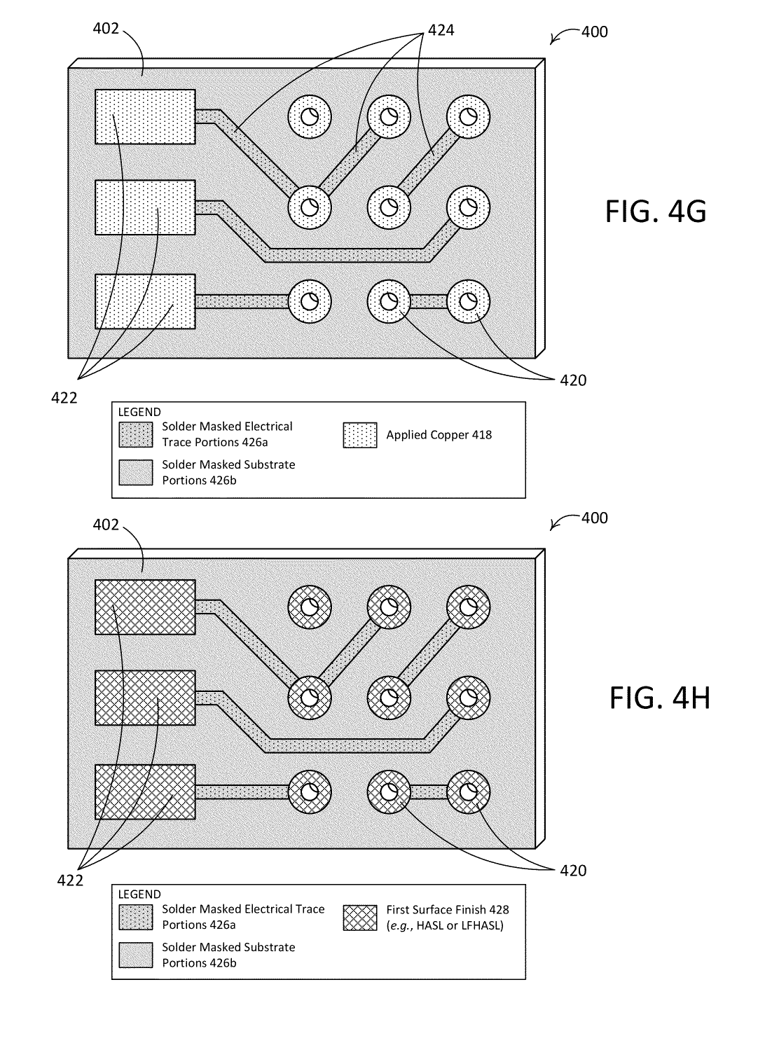

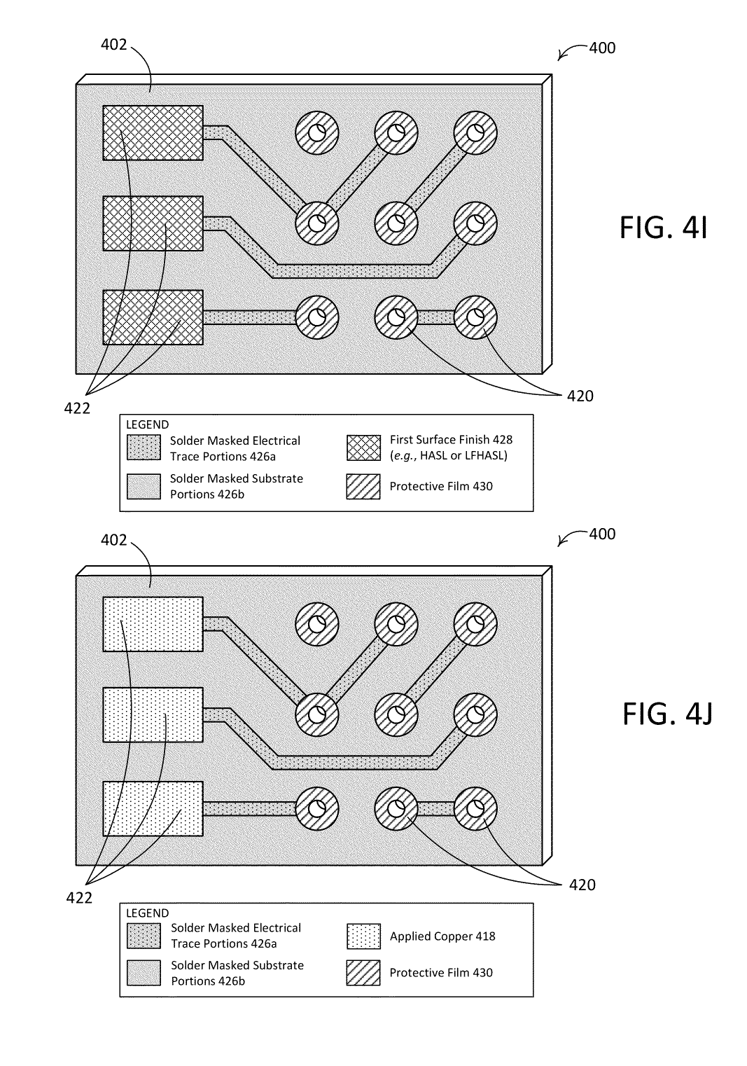

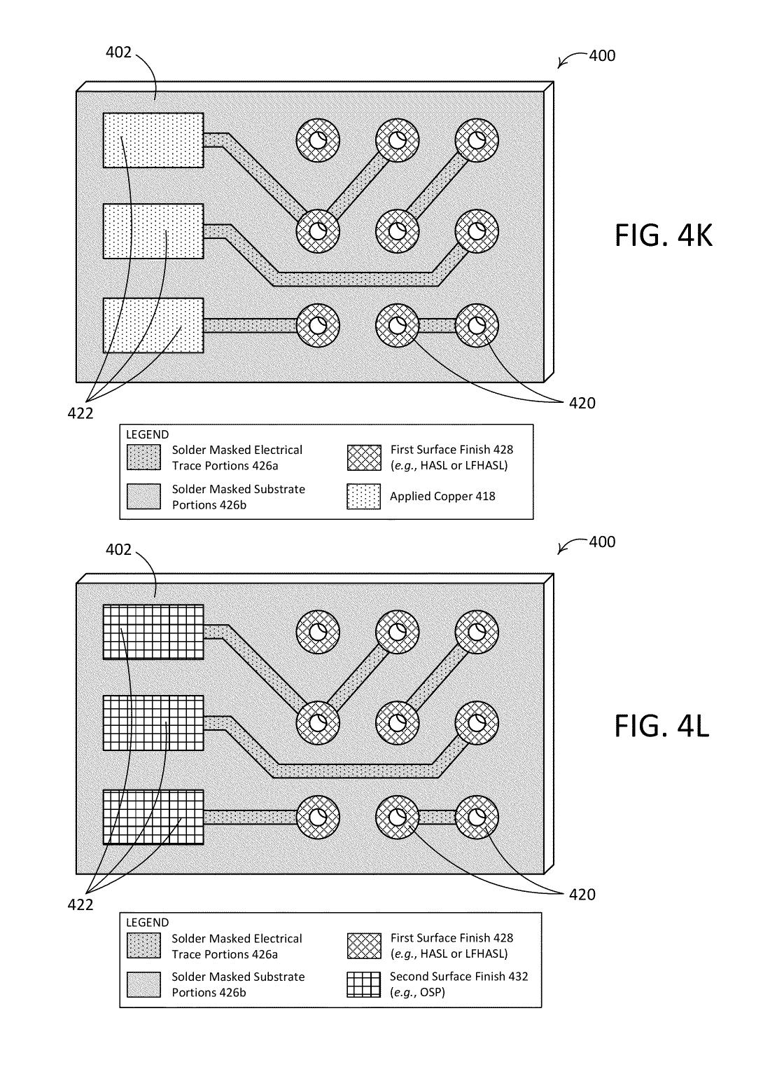

FIG. 3 is a flow diagram of an example process 300 for manufacturing a printed circuit board (PCB) having more than one surface finish (e.g., a PCB that includes at least two electrically conductive elements having respective surface finishes, wherein the respective surface finishes are different from one another). Such a PCB may be referred to herein as a multi-finish PCB. FIGS. 4A-4L depict an example multi-finish printed circuit board 400 at various stages of a manufacturing process, for instance the example manufacturing process 300 illustrated in FIG. 3. For example, a first surface finish 428 may be applied to one or more select electrically conductive elements of a multi-finish PCB and a second surface finish 432 that is different from the first surface finish 428 may be applied to one or more other electrically conductive elements of the multi-finish PCB.

The illustrated multi-finish PCB manufacturing process 300 begins at 302, where a raw material substrate 402 may be provided. The substrate 402 may include a substrate body 404 that defines opposed, substantially flat, first and second surfaces 406, 408. The first and second surfaces 406, 408 may be spaced apart from one another and may be bounded by a shared outer perimeter. The substrate body 404 may be made of any suitable material, such as glass reinforced fiber (fiberglass) epoxy resin, paper reinforced phenolic resin, or the like. The substrate 402 may include one or more layers of conductive material, such as copper foil 410, that may be bonded to one or both of the first and second surfaces 406, 408 of the substrate body 404, as illustrated in FIG. 4A.

At 304, one or more through holes 412 may be drilled through the substrate 402, for example as illustrated in FIG. 4B. The through holes 412 may extend from the first surface 406 of the substrate through to the second surface 408 of the substrate (e.g., through the substrate body 404 and the one or more layers of copper foil 410). The through holes 412 may be arranged in any desirable arrangement, for example in accordance with a printed circuit layout, or pattern, associated with the multi-finish printed circuit board 400. In accordance with an embodiment, respective locations of the through holes 412 relative to the substrate 402 may be translated into instructions for a computer controlled drilling machine that may be configured to drill the through holes 412.

At 306, respective inner surfaces of the through holes 412 may be coated (e.g., plated) with an electrically conductive material, such as copper, for example. The electrically conductive material may allow for electrical conductivity (e.g., transmission of electrical signals) via the through holes 412, for example between the first and second surfaces 406, 408 of the substrate 402 and/or between one or both of the first and second surfaces 406, 408 of the substrate 402 and respective electrical circuits embedded in one or more intermediate layers of the substrate body 404 (e.g., in one or more layers located between the first and second surfaces 406, 408 of the substrate 402).

At 308, a protective film 414, such as a photoresist material (e.g., a negative photoresist) may be applied to one or both of the first and second surfaces 406, 408, of the substrate 402. For example, a protective film 414 comprising a layer of negative photoresist may be pressed onto the copper foil 410 on the first surface 406 of the substrate body 404, or may be otherwise applied to the substrate 402 as desired.

At 310, a photomask 416 that may be representative of a printed circuit layout associated with the multi-finish printed circuit board 400 may be disposed onto the protective film 414. The photomask 416 may have one or more dark areas 416a that correspond to respective printed circuits that are to be defined on the multi-finish printed circuit board 400, for example on the first surface 406 of the substrate body 404. The photomask 416 may further comprise one or more lighter areas 416b that may be substantially clear, for example such that the protective film 414 underneath the photomask 416 is visible. FIG. 4C illustrates the substrate 402 with a protective film 414 applied to the first surface 406 of the substrate body 404 and with a photomask 416 disposed on the protective film 414.

The protective film 414 (e.g., a negative photoresist) may be cured with the photomask 416 in place. For example, in accordance with the illustrated embodiment, the substrate 402 may be exposed to ultraviolet light for an interval of time such that areas of the negative photoresist that are covered by lighter areas 416b of the photomask 416 are cured, while areas of the negative photoresist that are covered by dark areas 416a of the photomask 416 remain uncured. The cured (e.g., exposed, irradiated) areas of the negative photoresist may be insoluble to a photoresist developer, while the uncured (e.g., unexposed, protected) areas of the negative photoresist may be soluble (e.g., may be dissolved) by the photoresist developer.

At 312, the photomask 416 may be removed from the substrate 402 and uncured areas of the protective film 414 (e.g., negative photoresist) that may correspond to the respective printed circuits of the multi-finish printed circuit board 400 may be removed from the substrate 402. For example, the substrate 402 may be exposed to a photoresist developer (e.g., may be immersed in a developing agent) in order to strip away the soluble uncured areas of negative photoresist so as to expose underlying areas of copper foil 410. Respective cured areas of the negative photoresist may be insoluble with respect to the developing agent and may remain in place on the substrate 402, as illustrated in FIG. 4D.

At 314, the printed circuits of the multi-finish printed circuit board 400 may be defined, for instance by applying a conductive material to respective areas of the substrate 402 that were covered by uncured portions of the protective film 414. For example, copper 418 may be applied to the exposed areas of copper foil 410, for example by electroplating the copper 418 onto the exposed areas of copper foil 410. In accordance with an example copper electroplating process exposed areas of copper foil 410 operate as a cathode, such that the copper 418 is plated onto the exposed areas of copper foil 410, while areas of the substrate 402 that are covered by the protective film 414 (e.g., the negative photoresist) do not operate as a cathode and are not plated with copper 418.

The applied copper 418 may define one or more printed circuits of the multi-finish printed circuit board 400. For example, the printed circuits of the substrate 402 may include one or more electrically conductive elements disposed on the substrate body 404 (e.g., on the first surface 406 of the substrate body 404), such as one or more surface electrically conductive through hole pads 420 that correspond to respective ones of the through holes 412, one or more electrically conductive surface mount pads 422, and/or one or more electrically conductive traces 424 that may electrically connect respective electrically conductive elements of the multi-finish printed circuit board 400 to one another, as illustrated in FIG. 4E.

It should be appreciated that defining the printed circuits of the multi-finish printed circuit board 400 is not limited to a process that employs the illustrated photomask 416 in concert with negative photoresist. For example, a photomask having one or more lighter areas (e.g., clear areas) that correspond to respective printed circuits of the multi-finish printed circuit board 400, with a remainder of the photomask comprising dark areas, may be used. Such a photomask may be used in concert with a protective film comprising positive photoresist, such that portions of the positive photoresist that are exposed to light may become soluble to a photoresist developer while portions of the positive photoresist that are not exposed may remain insoluble with respect to the photoresist developer.

At 316, the applied copper 418 corresponding to the printed circuits may be coated with a protective material. For example, one or more layers of tin-lead may be plated (e.g., electroplated) onto the applied copper 418. The protective material may protect the electrical circuits during an etching process and/or may prevent oxidation of the applied copper 418.

At 318, protective film 414 that was cured may be removed from the substrate 402, such that copper foil 410 that does not correspond to the printed circuits is exposed. For example, the protective film 414 that was cured may be stripped from the substrate 402 using a solvent. Also at 318, copper foil 410 that was covered by the protective film 414 that was cured may be removed from the substrate 402, exposing bare substrate material in areas that do not correspond to the printed circuits, as illustrated in FIG. 4F. For example, the copper foil 410 may be etched (e.g., dissolved) from the first surface 406 of the substrate body 404 using an acid. The protective material applied to the printed circuits at 316 may prevent the applied copper 418 and copper foil 410 corresponding to the printed circuits from dissolving.

At 320, the protective material (e.g., plated tin-lead) may be removed from the printed circuits, for example by etching the protective material from the printed circuits using a suitable stripping agent (e.g., an acid). Also at 320, a solder masking material 426, such as a polymer, may be selectively applied to areas of the substrate 402. For example, the solder masking material 426 may be selectively applied to the electrically conductive traces 424 (e.g., defining one or more solder masked portions 426a of the electrically conductive traces 424) and to portions of exposed surface area of the substrate 402 (e.g., defining one or more solder masked portions 426b of the substrate 402), such that the electrically conductive through hole pads 420 and electrically conductive surface mount pads 422 are not covered by solder masking material 426 and remain exposed, as illustrated in FIG. 4G. The solder masking material 426 may provide a protective coating for the electrically conductive traces 424 traces of the multi-finish printed circuit board 400 and/or may prevent solder from bridging between electrically conductive elements of the multi-finish printed circuit board 400, thereby preventing short circuits.

Any suitable solder masking material and/or associated application process may be used. For example, the solder masking material may include one or more of an epoxy liquid, a liquid photoimageable solder mask (LPSM) ink, a dry film photoimageable solder mask (DFSM), or any other suitable material. After application, the solder masking material 426 may be cured (e.g., thermally cured).

At 322, a first surface finish 428 may be applied to one or more electrically conductive elements of the multi-finish printed circuit board 400, such as the electrically conductive through hole pads 420 and/or the electrically conductive surface mount pads 422. The first surface finish 428 may comprise a hot air solder leveling (HASL) surface finish or a lead-free hot air solder leveling (LF HASL) surface finish, for example. The first surface finish 428 may be applied to the electrically conductive through hole pads 420 and surface mount pads 422, respectively, of the substrate 402, as illustrated in FIG. 4H. The first surface finish 428 may be applied by immersing the substrate 402 in a bath of molten solder (e.g., lead-free solder). Excess solder may be removed subsequent to immersion, for example by air knives that blow the excess solder from the substrate 402. The first surface finish 428 (e.g., HASL or LF HASL) may enhance solderability characteristics of the electrically conductive through hole pads 420 and/or may prevent oxidation of the copper of the electrically conductive through hole pads 420, for example prior to the mounting and soldering of respective electrical components to the multi-finish printed circuit board 400.

A second surface finish 432 may be applied to one or more select electrically conductive elements of the multi-finish printed circuit board 400, for instance to enhance solderability characteristics of the select electrically conductive elements. For example, a second surface finish 432 comprising an organic surface protection (OSP) surface finish may be applied to one or more of the electrically conductive surface mount pads 422 of the multi-finish printed circuit board 400, such as all of the electrically conductive surface mount pads 422. A first surface finish 428 (e.g., a HASL surface finish or an LF HASL surface finish) may be removed from the select electrically conductive elements (e.g., the electrically conductive surface mount pads 422) prior to application of the second surface finish 432. In this regard, the second surface finish 432 may be applied to at least respective portions of (e.g., substantially the entireties of) the select electrically conductive elements from which an initial surface finish (e.g., the first surface finish 428) is removed.

At 324, a protective film may be applied to one or more electrically conductive elements of the multi-finish printed circuit board 400 that are to retain the first surface finish 428. For example, a protective film 430 (e.g., a photoresist) may be applied to the first surface finish 428 of the electrically conductive through hole pads 420, as illustrated in FIG. 4I. The protective film 430 may operate to protect the first surface finish 428 of the electrically conductive through hole pads 420 during removal of the first surface finish 428 from the electrically conductive surface mount pads 422. The protective film 430 may be, for example, a layer of dry film photoresist such as DuPont™ Riston® MM120. One or more layers of the protective film may be applied to the one or more electrically conductive elements that are to retain the first surface finish 428. For example, two layers of the protective film 430 may be applied to the first surface finish 428 of the electrically conductive through hole pads 420, in order to protect the first surface finish 428 of the electrically conductive through hole pads 420 during removal of the first surface finish 428 from the electrically conductive surface mount pads 422.

At 326, the first surface finish 428 may be removed from the select electrically conductive elements that are not protected by the protective film 430 (e.g., the electrically conductive surface mount pads 422), such that the applied copper 418 of the select electrically conductive elements is exposed, as illustrated in FIG. 4J. For example, the first surface finish 428 may be removed from the electrically conductive surface mount pads 422 with a stripping agent, such as NITRO strip NS-1700. The stripping agent may be applied to the substrate 402 one or more times (e.g., as required), such that substantially all of the first surface finish 428 is removed from the electrically conductive surface mount pads 422. The process of removing the first surface finish 428 from the electrically conductive surface mount pads 422 may be carried out in an operating temperature range of approximately 80° F. to approximately 100° F., for example.

At 328, the protective film 430 may be removed from the substrate 402, such that the first surface finish 428 (e.g., the HASL or LF HASL) of the electrically conductive through hole pads 420 is exposed, as illustrated in FIG. 4K. For example, the DuPont™ Riston® MM120 dry film photoresist may be removed from the electrically conductive through hole pads 420 using a stripping agent, such as AUTOSTRIP RS-5510. The process of removing the protective film 430 from the electrically conductive through hole pads 420 may be carried out in an operating temperature range of approximately 120° F. to approximately 140° F., for example.

Once the protective film 430 has been removed, the substrate 402 may be subjected to a cleaning process, for instance in preparation for applying the second surface finish 432 to the select electrically conductive elements (e.g., the electrically conductive surface mount pads 422). The cleaning process may remove surface contaminants and/or residues that may be present on the applied copper 418 of the electrically conductive surface mount pads 422. A cleaning process may include immersing the substrate 402 in a solution comprising 5% sulfuric acid, for example.

At 330, the example process 300 for manufacturing the multi-finish printed circuit board 400 may end with the application of a second surface finish 432 to one or more select electrically conductive elements (e.g., the electrically conductive surface mount pads 422). For example, a second surface finish 432 comprising an organic surface protector (OSP) surface finish 432 may be applied to the electrically conductive surface mount pads 422, as illustrated in FIG. 4L. The OSP surface finish 432 may be applied by immersing the substrate 402 in an OSP surface finish. The OSP surface finish 432 may adhere only to areas of bare copper, such as exposed areas of the applied copper 418 corresponding to the electrically conductive surface mount pads 422. The OSP surface finish 432 may enhance solderability characteristics of the electrically conductive surface mount pads 422 and/or may prevent oxidation of the copper of the electrically conductive surface mount pads 422, for example prior to the mounting and soldering of respective electrical components to the multi-finish printed circuit board 400.

In accordance with the illustrated embodiment, the multi-finish printed circuit board 400 may include a substrate body 404, a first electrically conductive element (e.g., an electrically conductive through hole pad 420) disposed on the substrate body 404 and a second electrically conductive element (e.g., an electrically conductive surface mount pad 422) disposed on the substrate body 404. The first electrically conductive element may have a first surface finish 428 (e.g., a HASL surface finish or an LF HASL surface finish) and the second electrically conductive element may have a second surface finish 432 (e.g., an OSP surface finish) that is different from the first surface finish 428.

It should be appreciated that the electrically conductive elements of the multi-finish printed circuit board 400 are not limited to the illustrated materials used for the first and second surface finishes 428, 432 (e.g., HASL or LF HASL and OSP, respectively) and that other suitable first and/or second surface finishes may be applied to one or more electrically conductive elements, such as all of the electrically conductive elements, of the multi-finish printed circuit board 400. For example, alternative first and/or second surface finishes may include immersion tin, immersion silver, electroless nickel immersion gold (ENIG), electroless nickel electroless palladium immersion gold (ENEPIG), or other suitable surface finish materials. It should further be appreciated that all of the electrically conductive through hole pads 420 of the multi-finish printed circuit board 400 need not be finished in the same surface finish (e.g., HASL). Moreover, all of the electrically conductive surface mount pads 422 of the multi-finish printed circuit board 400 need not be finished in the same surface finish (e.g., OSP surface finish). It should further still be appreciated that the multi-finish printed circuit board 400 is not limited to two surface finishes (e.g., as applied to the electrically conductive elements), and that the multi-finish printed circuit board 400 may have any suitable number of surface finishes, such as two surfaces, three surface finishes, four surface finishes, and so on.

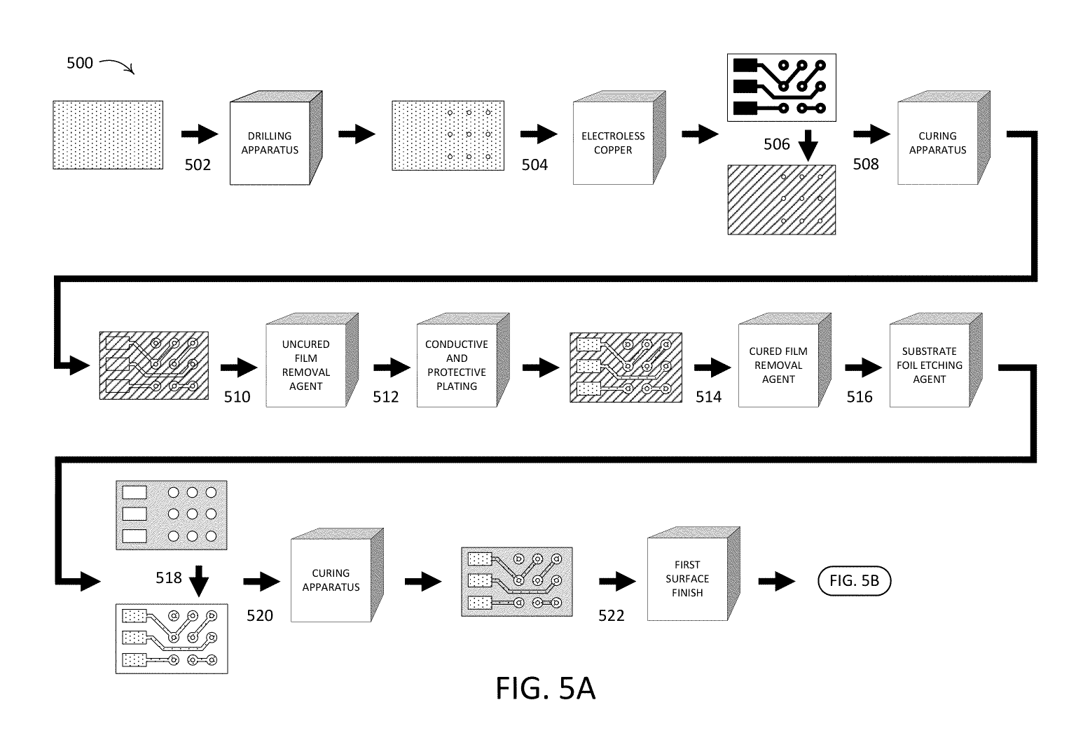

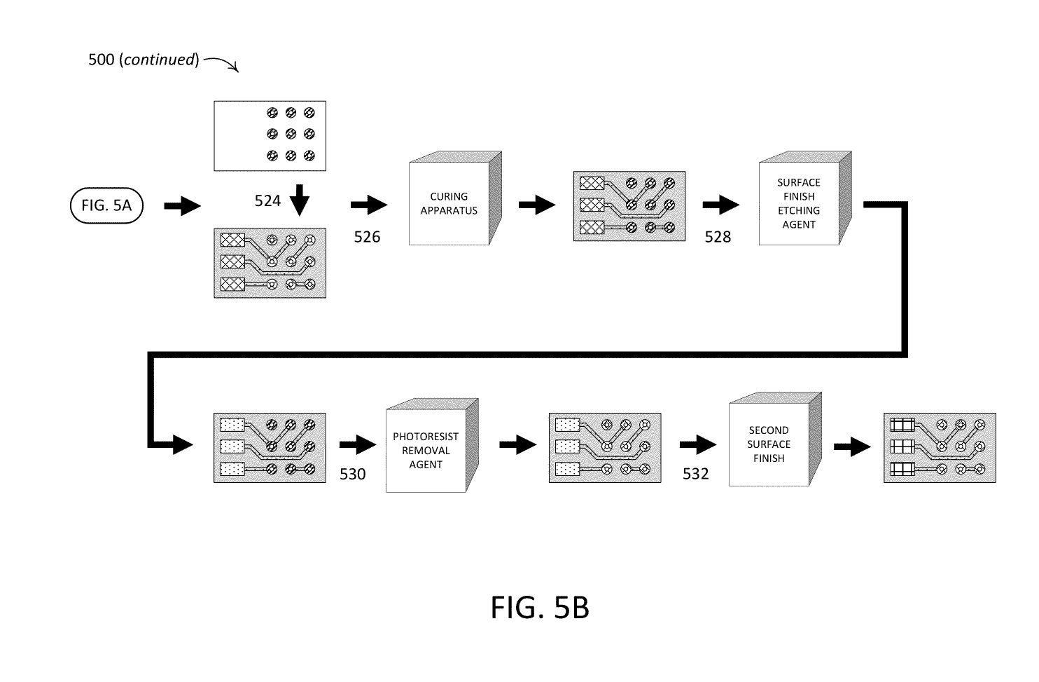

FIGS. 5A and 5B provide a detailed flow diagram 500 illustrating an example process for manufacturing (e.g., making) the multi-finish printed circuit board 400, for example in accordance with the example process 300 illustrated in FIG. 3. At 502, a substrate (e.g., the substrate 402 illustrated in FIG. 4A) may be provided to a drilling apparatus, such as a computer numerical control (CNC) machine. The drilling apparatus may operate to drill one or more through holes in the substrate, for example as described herein with reference to FIGS. 3 and 4B.

At 504, the substrate may be provided to a plating apparatus, such as an electroless copper plating machine. The plating apparatus may apply a layer of copper to the respective inner surfaces of each of the through holes.

At 506, a protective film, such as a photoresist, may be applied to the substrate and a photomask may be disposed on the protective film, for example as described herein with reference to FIGS. 3 and 4C. At 508, the substrate, with the photomask in place, may be provided to a curing apparatus, such as an ultraviolet light emitting curing apparatus. The curing apparatus may irradiate portions of the photoresist that are exposed by the photomask with ultraviolet light, such that the irradiated portions of the photoresist become insoluble.

At 510, the substrate may be exposed to a photoresist developing agent that may remove (e.g., strip away) soluble portions of the photoresist, for example portions of the photoresist that were protected from ultraviolet irradiation by the photomask. For example, the substrate may be provided to a dip tank apparatus containing the photoresist developing agent and the substrate may be immersed in the photoresist developing agent.

At 512, the substrate may be provided to a conductive plating apparatus (e.g., a copper electroplating apparatus) and a protective plating apparatus (e.g., a tin electroplating apparatus). The conductive plating apparatus may, for example, operate to electroplate one or more layers of copper onto the substrate in areas that correspond to the removed soluble portions of photoresist. The protective plating apparatus may operate to electroplate a layer of protective material (e.g., tin-lead) onto the one or more layers of electroplated copper. The conductive plating apparatus and the protective plating apparatus may be a single apparatus or may be separate apparatuses.

At 514, the substrate may be exposed to a photoresist removal agent (e.g., a photoresist solvent). For example, the substrate may be provided to a dip tank apparatus containing the photoresist removal agent and the substrate may be immersed in the photoresist removal agent. The photoresist removal agent may dissolve the irradiated, insoluble portions of the photoresist, thereby removing substantially all remaining photoresist from the substrate.

At 516, the substrate may be exposed to an etching agent (e.g., an acid). For example, the substrate may be provided to a dip tank apparatus containing the etching agent and the substrate may be immersed in the etching agent. The etching agent may dissolve copper foil from the surface of the substrate, for example in areas that correspond to the insoluble portions of the photoresist, such that one or more bare surfaces of substrate are exposed.

At 518, a solder masking material may be applied to select portions of the substrate, such that one or more areas of electroplated copper corresponding to respective electrically conductive elements remain unmasked, for example as described herein with reference to FIGS. 3 and 4G. For example, the substrate may be provided to a spray tank apparatus and the solder masking material may be sprayed onto the substrate. Alternatively, the substrate may be provided to a silk screening apparatus and the solder masking material may be silkscreened onto the substrate. At 520, the substrate may be provided to a curing apparatus that may cure the solder masking material applied to the substrate. The curing apparatus may be the same or different from the curing apparatus used at 508.

At 522, the substrate may be provided to a first surface finish apparatus configured to apply a first surface finish (e.g., a HASL surface finish or an LF HASL surface finish) to one or more electrically conductive elements of the substrate. For example, the substrate may be provided to a dip tank containing molten solder and may be immersed in the molten solder. The dip tank may be a vertical dip tank and/or a horizontal dip tank. The molten solder may adhere to areas of exposed copper on the substrate, for example to electrically conductive through hole pads disposed on the substrate and/or to electrically conductive surface mount pads disposed on the substrate. Excess solder may be removed subsequent to immersion, for example by air knives that blow the excess solder from the substrate.

At 524, a protective film (e.g., a dry film photoresist) may be applied to one or more electrically conductive elements of the substrate that are to retain the first surface finish (e.g., electrically conductive through hole pads). The protective film may be a mask that covers the one or more electrically conductive elements of the substrate that are to retain the first surface finish and allows one or more electrically conductive elements that are to receive a second surface finish to be exposed. For example, the substrate may be provided to a spray tank apparatus and the dry film photoresist may be sprayed onto the substrate. Alternatively, the substrate may be provided to a silk screening apparatus and the dry film photoresist may be silkscreened onto the substrate. At 526, the substrate may be provided to a curing apparatus that may cure the dry film photoresist applied to the substrate. The curing apparatus may be the same or different from the curing apparatuses used at one or both of 508 and 520.

At 528, the substrate may be exposed to an etching agent (e.g., an acid). For example, the substrate may be provided to a dip tank apparatus containing the etching agent and the substrate may be immersed in the etching agent. The etching agent may dissolve the first surface finish from one or more electrically conductive elements of the substrate to which the dry film photoresist was not applied (e.g., electrically conductive surface mount pads), for example such that bare copper of the electrically conductive surface mount pads is exposed. The dip tank apparatus may be the same or different from the dip tank apparatus used at 516.

At 530, the substrate may be exposed to a photoresist removal agent (e.g., a photoresist solvent). For example, the substrate may be provided to a dip tank apparatus containing the photoresist removal agent and the substrate may be immersed in the photoresist removal agent. The photoresist removal agent may dissolve the cured dry film photoresist mask, for example such that one or more electrically conductive elements of the substrate to which the dry film photoresist was applied (e.g., electrically conductive through hole pads) are exposed. The dip tank apparatus may be the same or different from the dip tank apparatus used at 514.

At 532, the substrate may be provided to a second surface finish apparatus configured to apply a second surface finish (e.g., an OSP surface finish) to one or more electrically conductive elements of the substrate. For example, the substrate may be provided to a dip tank containing OSP surface finish and may be immersed in the OSP surface finish. The dip tank may be a vertical dip tank and/or a horizontal dip tank. The OSP surface finish may adhere to areas of exposed copper on the substrate (e.g., to electrically conductive surface mount pads from which the HASL surface finish was removed). The first surface finish apparatus and the second surface finish apparatus may be a single apparatus or may be separate apparatuses.

It should be appreciated that the manufacture of the multi-finish printed circuit board 400 is not limited to the illustrated example process comprising applying both the first and second surface finishes to respective electrically conductive elements of the substrate. For example, a portion of the illustrated example process, for instance from 524-532, may be applied to a printed circuit board with electrically conductive elements to which an initial, single surface finish has been applied. It should further be appreciated that manufacture of the multi-finish printed circuit board 400 is not limited to the illustrated order of manufacturing process steps, and that one or more steps of the manufacturing process may be performed in an alternative order and/or may be omitted. It should further still be appreciated that the manufacture of a multi-finish printed circuit board is not limited to the illustrated single-sided printed multi-finish printed circuit board, and that the manufacturing processes described herein may be similarly employed to manufacture double-sided printed circuit boards and/or multi-layered printed circuit boards.

1. A printed circuit board, comprising:
a substrate body;
an electrically conductive through hole pad disposed on the substrate body, the through hole pad having a hot air solder leveling (HASL) surface finish applied thereto; and
an electrically conductive surface mount pad disposed on the substrate body, the surface mount pad having an organic surface protection (OSP) surface finish applied thereto.

2. The printed circuit board of claim 1, wherein the HASL surface finish is applied to only the electrically conductive through hole pad and the OSP surface finish is applied to only the electrically conductive surface mount pad.

3. The printed circuit board of claim 1, wherein the OSP surface finish is applied to a portion of the electrically conductive surface mount pad from which an initial surface finish was removed.

4. The printed circuit board of claim 1, wherein the HASL surface finish is a lead-free HASL surface finish.

5. A printed circuit board, comprising:
a substrate body;
a first electrically conductive element disposed on the substrate body, the first electrically conductive element having a first surface finish; and
a second electrically conductive element disposed on the substrate body, the second electrically conductive element having a second surface finish that is different from the first surface finish.

6. The printed circuit board of claim 5, wherein the first electrically conductive element comprises a through hole pad and the second electrically conductive element comprises a surface mount pad.

7. The printed circuit board of claim 5, wherein the first surface finish comprises a HASL surface finish.

8. The printed circuit board of claim 5, wherein the first surface finish comprises a lead-free HASL surface finish.

9. The printed circuit board of claim 5, wherein the second surface finish comprises an OSP surface finish.

10. The printed circuit board of claim 5, wherein the first surface finish comprises a HASL surface finish and the second surface finish comprises an OSP surface finish.

11. The printed circuit board of claim 5, wherein the second surface finish is applied to a portion of the second electrically conductive element from which an initial surface finish was removed.

12. The printed circuit board of claim 11, wherein the initial surface finish comprises the first surface finish.

13. The printed circuit board of claim 12, wherein the first surface finish comprises a HASL surface finish and the second surface finish comprises an OSP surface finish.

14. A method for manufacturing a printed circuit board, the method comprising:
providing a substrate having a substrate body and first and second electrically conductive elements disposed on the substrate body;
applying a first surface finish to the first electrically conductive element; and
applying a second surface finish to the second electrically conductive element, wherein the second surface finish is different from the first surface finish.

15. The method of claim 14, wherein the first surface finish is applied to the first and second electrically conductive elements, the method further comprising:
removing the first surface finish from the second electrically conductive element before applying the second surface finish thereto.

16. The method of claim 15, wherein the first surface finish comprises a HASL surface finish and the second surface finish comprises an OSP surface finish.

17. The method of claim 16, wherein the first electrically conductive element comprises a through hole pad and the second electrically conductive element comprises a surface mount pad.

18. The method of claim 14, wherein the first surface finish is applied to the first and second electrically conductive elements, the method further comprising:
applying a mask to the substrate such that the mask covers the first electrically conductive element and allows the second electrically conductive element to be exposed;
removing the first surface finish from the second electrically conductive element before applying the second surface finish thereto; and
removing the mask.

19. The method of claim 18, wherein the mask is removed before applying the second surface finish to the second electrically conductive element.

20. The method of claim 18, wherein the first electrically conductive element comprises a through hole pad and the second electrically conductive element comprises a surface mount pad.

21. The method of claim 18, wherein the first surface finish comprises a HASL surface finish and the second surface finish comprises an OSP surface finish.

22. A printed circuit board manufactured in accordance with a process, the process comprising:
providing a substrate having a substrate body and first and second electrically conductive elements disposed on the substrate body;
applying a first surface finish to the first electrically conductive element; and
applying a second surface finish to the second electrically conductive element, wherein the second surface finish is different from the first surface finish.

23. The printed circuit board of claim 22, wherein the first surface finish is applied to the first and second electrically conductive elements, the process further comprising:
removing the first surface finish from the second electrically conductive element before applying the second surface finish thereto.

24. The printed circuit board of claim 23, wherein the first surface finish comprises a HASL surface finish and the second surface finish comprises an OSP surface finish.

25. The printed circuit board of claim 24, wherein the first electrically conductive element comprises a through hole pad and the second electrically conductive element comprises a surface mount pad.

26. The printed circuit board of claim 22, wherein the first surface finish is applied to the first and second electrically conductive elements, the process further comprising:
applying a mask to the substrate such that the mask covers the first electrically conductive element and allows the second electrically conductive element to be exposed;
removing the first surface finish from the second electrically conductive element before applying the second surface finish thereto; and
removing the mask.

27. The printed circuit board of claim 26, wherein the mask is removed before applying the second surface finish to the second electrically conductive element.

28. The printed circuit board of claim 26, wherein the first electrically conductive element comprises a through hole pad and the second electrically conductive element comprises a surface mount pad.

29. The printed circuit board of claim 26, wherein the first surface finish comprises a HASL surface finish and the second surface finish comprises an OSP surface finish.
